(19) United States
(12) Patent Application Publication
(10) Pub. No.: US 2015/0124231 A1
(43) Pub. Date: May 7, 2015

(54) Assembly For Modifying Properties Of A Plurality Of Radiation Beams, A Lithography Apparatus, A Method Of Modifying Properties Of A Plurality Of Radiation Beams And A Device Manufacturing Method

(71) Applicant: ASML Netherlands B.V., Veldhoven (NL)

(72) Inventors: Heine Melle Mulder, Veldhoven (NL); Pieter Willem Herman De Jager, Middelbeers (NL)

(73) Assignee: ASML Netherlands B.V., Veldhoven (NL)

(21) Appl. No.: 14/398,043

(22) PCT Filed: May 6, 2013
(86) PCT No.: PCT/EP2013/059347

§ 371 Date: Oct. 30, 2014

Related U.S. Application Data
(60) Provisional application No. 61/654,575, filed on Jun. 1, 2012.
(60) Provisional application No. 61/668,924, filed on Jul. 6, 2012.

(51) Int. Cl. G03F 7/20

(52) U.S. Cl. CPC G03F 7/70025
USPC 355/67; 385/2

(57) ABSTRACT

An assembly to modify a property of a plurality of radiation beams, the assembly including a plurality of waveguides configured to guide the plurality of radiation beams closer together, and a frequency multiplying device configured to receive the plurality of radiation beams guided by the plurality of waveguides and generate a corresponding plurality of radiation beams having frequencies that are an integer multiple higher. Also described are a corresponding lithography apparatus, method of modifying a property of a plurality of radiation beams and device manufacturing method.

### CROSS-REFERENCE TO RELATED APPLICATIONS

This application claims benefit of U.S. provisional application 61/654,575 which was filed on Jun. 1, 2012 and also of U.S. provisional application 61/668,924 which was filed on Jul. 6, 2012 and each of which are incorporated herein in its entirety by reference.

### FIELD

The present invention relates to an assembly to modify one or more properties of a plurality of radiation beams, a lithography apparatus, a method of modifying one or more properties of a plurality of radiation beams and a device manufacturing method.

### BACKGROUND

A lithographic or exposure apparatus is a machine that applies a desired pattern onto a substrate or part of a substrate. The apparatus may be used, for example, in the manufacture of integrated circuits (ICs), flat panel displays and other devices or structures having fine features. In a conventional lithographic or exposure apparatus, a patterning device, which may be referred to as a mask or a reticle, may be used to generate a circuit pattern corresponding to an individual layer of the IC, flat panel display, or other device). This pattern may transferred on (part of) the substrate (e.g. silicon wafer or a glass plate), e.g. via imaging onto a layer of radiation-sensitive material (resist) provided on the substrate.

Instead of a circuit pattern, the patterning device may be used to generate other patterns, for example a color filter pattern, or a matrix of dots. Instead of a conventional mask, the patterning device may comprise a patterning array that comprises an array of individually controllable elements that generate the circuit or other applicable pattern. An advantage of such a “maskless” system compared to a conventional mask-based system is that the pattern can be provided and/or changed more quickly and for less cost.

Thus, a maskless system includes a programmable patterning device (e.g., a spatial light modulator, a contrast device, etc.). The programmable patterning device is programmed (e.g., electronically or optically) to form the desired patterned beam using the array of individually controllable elements. Types of programmable patterning devices include micro-mirror arrays, liquid crystal display (LCD) arrays, grating light valve arrays, arrays of self-emissive contrast devices and the like. A programmable patterning device could also be formed from an electro-optical deflector, configured for example to move spots of radiation projected onto a target (e.g., the substrate) or to intermittently direct a radiation beam away from the target (e.g., the substrate), for example to a radiation beam absorber. In either such arrangement, the radiation beam may be continuous.

### SUMMARY

405 nm single mode laser diodes may be used as the self-emissive contrast devices of the programmable patterning device. In such an arrangement one or more of a single mode optical fiber (a type of waveguide) may be used to transport and/or guide the radiation. A high power 405 nm single mode laser diode can be expensive and may have a limited lifetime. Furthermore, there may be concerns with the lifetime of an optical fiber. For example, the entrance and/or exit surfaces of an optical fiber may degrade quickly (e.g., in a matter of days without special protection). With protection, the lifetime can be extended to about 3000 hours according to pigtailed laser lifetime.

For future applications that may use higher frequency radiation, the problems of fiber or waveguide lifetime and/or laser diode cost/availability may increase.

Another issue arises where a laser diodes is run continuously above a lasing threshold. This may be necessary to achieve rapid and accurate switching for example. Maintaining the laser diode above the threshold may increase the background radiation level, which may even be non-uniform. This effect may lead to contrast loss.

A further issue is the beam pointing stability of a laser diode, especially for a plurality of laser diodes and when a pitch between laser diodes is significantly demagnified to come to the desired pitch of spots on the target. This is the case because a beam pointing error transfers into a telecentricity error at target level in a manner inversely proportional to the demagnification of the laser diode pitch.

It is desirable, for example, to address at least one of the problems mentioned above or another problem in the art.

According to an embodiment, there is provided an assembly to modify a property of a plurality of radiation beams, the assembly comprising: a plurality of waveguides configured to guide the plurality of radiation beams closer together; and a frequency multiplying device configured to receive the plurality of radiation beams guided by the plurality of waveguides and generate a corresponding plurality of radiation beams having frequencies that are an integer multiple higher.

According to an embodiment, there is provided an exposure apparatus, comprising: a radiation source to provide a plurality of individually controllable radiation beams, the radiation source comprising: a plurality of waveguides configured to guide the plurality of radiation beams closer together, and a frequency multiplying device configured to receive the plurality of radiation beams guided by the plurality of waveguides and generate a corresponding plurality of radiation beams having frequencies that are an integer multiple higher; and a projection system for projecting each of the radiation beams onto a respective location on a target.

According to an embodiment, there is provided an exposure apparatus, comprising: a radiation source to provide a plurality of individually controllable radiation beams, the radiation source comprising a plurality of vertical-external-cavity surface-emitting-lasers (VECSELs); and a projection system configured to project each of the radiation beams onto a respective location on a target.

According to an embodiment, there is provided a method of modifying a property of a plurality of radiation beams, the method comprising: using a plurality of waveguides to guide the radiation beams closer together; and using a frequency multiplying device to receive the plurality of radiation beams guided by the plurality of waveguides and generate a corresponding plurality of radiation beams having frequencies that are an integer multiple higher.

According to an embodiment, there is provided a device manufacturing method, comprising: using a plurality of waveguides to guide a plurality of individually controllable radiation beams closer together; using a frequency multiplying device to receive the plurality of radiation beams guided by the plurality of waveguides and generate a corresponding plurality of radiation beams having frequencies that are an integer multiple higher; and projecting each of the radiation beams onto a respective location on a target.

According to an embodiment, there is provided a device manufacturing method, comprising: providing a plurality of individually controllable radiation beams using a plurality of vertical-external-cavity surface-emitting-lasers (VECSELs); and projecting each of the radiation beams onto a respective location on a target.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a part of a lithographic or exposure apparatus according to an embodiment of the invention;

FIG. 2 depicts a top view of a part of the apparatus of FIG. 1 according to an embodiment of the invention;

FIG. 3 depicts a highly schematic, perspective view of a part of a lithographic or exposure apparatus according to an embodiment of the invention;

FIG. 4 depicts a schematic top view of projections by the apparatus according to FIG. 3 onto a substrate according to an embodiment of the invention;

FIG. 5 depicts, in cross-section, a part of an embodiment of the invention;

FIG. 6 depicts a plurality of waveguides and a frequency multiplying device;

FIG. 7 depicts a radiation source comprising an array of VECSELs;

FIG. 8 depicts a combination of a radiation source comprising VECSELs and a frequency multiplying device; and

FIG. 9 depicts an example VECSEL configuration.

### DETAILED DESCRIPTION

An embodiment of the present invention relates to an apparatus that may include a programmable patterning device that may, for example, be comprised of an array or arrays of self-emissive contrast devices. Further information regarding such an apparatus may be found in PCT patent application publication no. WO 2010/032224 A2, U.S. patent application publication no. US 2011-0188016, U.S. patent application No. 61/473,636 and U.S. patent application No. 61/524,190 which are hereby incorporated by reference in their entireties. An embodiment of the present invention, however, may be used with any form of programmable patterning device including, for example, those discussed above.

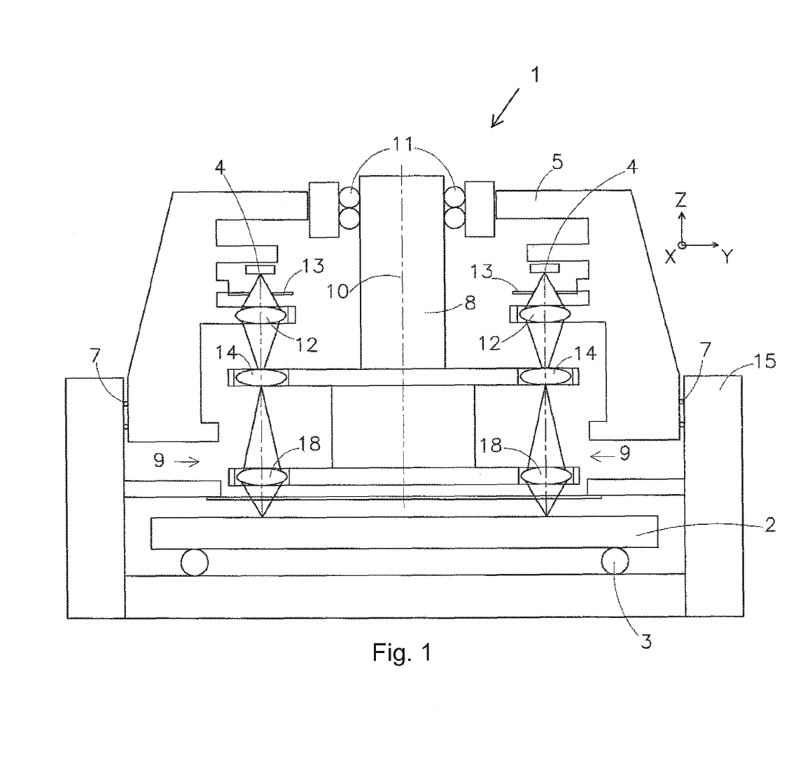

FIG. 1 schematically depicts a schematic cross-sectional side view of a part of a lithographic or exposure apparatus. In this embodiment, the apparatus has individually controllable elements substantially stationary in the X-Y plane as discussed further below although it need not be the case. The lithographic or exposure apparatus 1 comprises a substrate table 2 to hold a substrate, and a positioning device 3 to move the substrate table 2 in up to 6 degrees of freedom. The substrate may be a resist-coated substrate. In an embodiment, the substrate is a wafer. In an embodiment, the substrate is a polygonal (e.g. rectangular) substrate. In an embodiment, the substrate is a glass plate. In an embodiment, the substrate is a plastic substrate. In an embodiment, the substrate is a foil. In an embodiment, the apparatus is suitable for roll-to-roll manufacturing.

The apparatus 1 further comprises a plurality of individually controllable self-emissive contrast devices 4 configured to emit a plurality of beams. In an embodiment, the self-emissive contrast device 4 is a radiation emitting diode, such as a light emitting diode (LED), an organic LED (OLED), a polymer LED (PLED), or a laser diode (e.g., a solid state laser diode). In an embodiment, each of the individually controllable elements 4 is a blue-violet laser diode (e.g., Sanyo model no. DL-3146-151). Such diodes may be supplied by companies such as Sanyo, Nichia, Osram, and Nitride. In an embodiment, the diode emits UV radiation, e.g., having a wavelength of about 365 nm or about 405 nm. In an embodiment, the diode can provide an output power selected from the range of 0.5-200 mW. In an embodiment, the size of laser diode (naked die) is selected from the range of 100-800 micrometers. In an embodiment, the laser diode has an emission area selected from the range of 0.5-5 micrometers². In an embodiment, the laser diode has a divergence angle selected from the range of 5-44 degrees. In an embodiment, the diodes have a configuration (e.g., emission area, divergence angle, output power, etc.) to provide a total brightness more than or equal to about 6.4×10⁸ W/(m².sr).

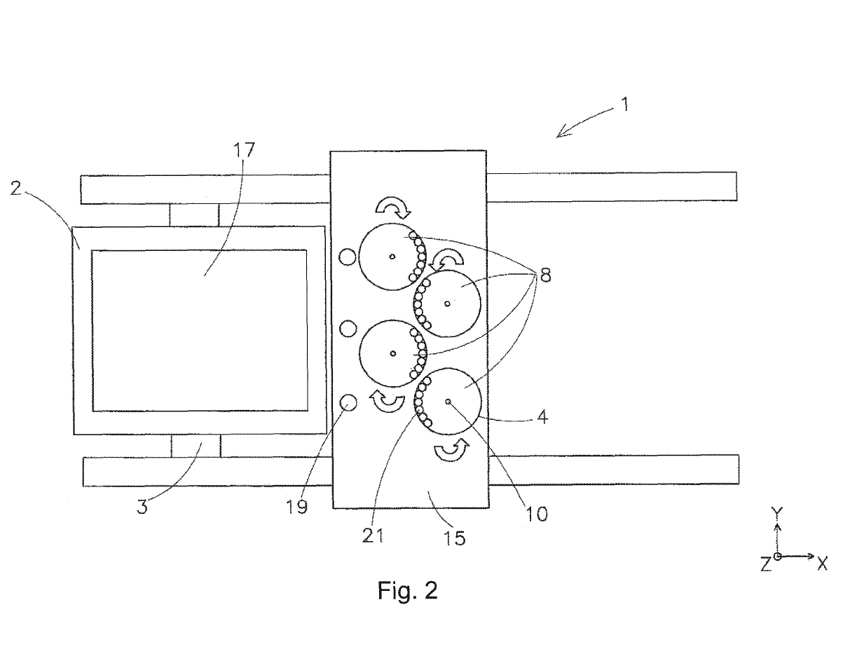

The self-emissive contrast devices 4 are arranged on a frame 5 and may extend along the Y-direction and/or the X direction. While one frame 5 is shown, the apparatus may have a plurality of frames 5 as shown in FIG. 2. Further arranged on the frame 5 is lens 12. Frame 5 and thus self-emissive contrast device 4 and lens 12 are substantially stationary in the X-Y plane. Frame 5, self-emissive contrast device 4 and lens 12 may be moved in the Z-direction by actuator 7. Alternatively or additionally, lens 12 may be moved in the Z-direction by an actuator related to this particular lens. Optionally, each lens 12 may be provided with an actuator.

The self-emissive contrast device 4 may be configured to emit a beam and the projection system 12, 14 and 18 may be configured to project the beam onto a target portion of the substrate. The self-emissive contrast device 4 and the projection system form an optical column. The apparatus 1 may comprise an actuator (e.g. motor) 11 to move the optical column or a part thereof with respect to the substrate. Frame 8 with arranged thereon field lens 14 and imaging lens 18 may be rotatable with the actuator. A combination of field lens 14 and imaging lens 18 forms movable optics 9. In use, the frame 8 rotates about its own axis 10, for example, in the directions shown by the arrows in FIG. 2. The frame 8 is rotated about the axis 10 using an actuator (e.g. motor) 11. Further, the frame 8 may be moved in a Z direction by motor 7 so that the movable optics 9 may be displaced relative to the substrate table 2.

An aperture structure 13 having an aperture therein may be located above lens 12 between the lens 12 and the self-emissive contrast device 4. The aperture structure 13 can limit diffraction effects of the lens 12, the associated self-emissive contrast device 4, and/or of an adjacent lens 12/self-emissive contrast device 4.

The depicted apparatus may be used by rotating the frame 8 and simultaneously moving the substrate on the substrate table 2 underneath the optical column. The self-emissive contrast device 4 can emit a beam through the lenses 12, 14, and 18 when the lenses are substantially aligned with each other. By moving the lenses 14 and 18, the image of the beam on the substrate is scanned over a portion of the substrate. By simultaneously moving the substrate on the substrate table 2 underneath the optical column, the portion of the substrate which is subjected to an image of the self-emissive contrast device 4 is also moving. By switching the self-emissive contrast device 4 “on” and “off” (e.g., having no output or output below a threshold when it is “off” and having an output above a threshold when it is “on”) at high speed under control of a controller, controlling the rotation of the optical column or part thereof, controlling the intensity of the self-emissive contrast device 4, and controlling the speed of the substrate, a desired pattern can be imaged in the resist layer on the substrate.

FIG. 2 depicts a schematic top view of the apparatus of FIG. 1 having self-emissive contrast devices 4. Like the apparatus 1 shown in FIG. 1, the apparatus 1 comprises a substrate table 2 to hold a substrate 17, a positioning device 3 to move the substrate table 2 in up to 6 degrees of freedom, an alignment/level sensor 19 to determine alignment between the self-emissive contrast device 4 and the substrate 17, and to determine whether the substrate 17 is at level with respect to the projection of the self-emissive contrast device 4. As depicted the substrate 17 has a rectangular shape, however also or alternatively round substrates may be processed.

The self-emissive contrast device 4 is arranged on a frame 15. The self-emissive contrast device 4 may be a radiation emitting diode, e.g., a laser diode, for instance a blue-violet laser diode. As shown in FIG. 2, the self-emissive contrast devices 4 may be arranged into an array 21 extending in the X-Y plane.

The array 21 may be an elongate line. In an embodiment, the array 21 may be a single dimensional array of self-emissive contrast devices 4. In an embodiment, the array 21 may be a two dimensional array of self-emissive contrast device 4.

A rotating frame 8 may be provided which may be rotating in a direction depicted by the arrow. The rotating frame may be provided with lenses 14, 18 (show in FIG. 1) to provide an image of each of the self-emissive contrast devices 4. The apparatus may be provided with an actuator to rotate the optical column comprising the frame 8 and the lenses 14, 18 with respect to the substrate.

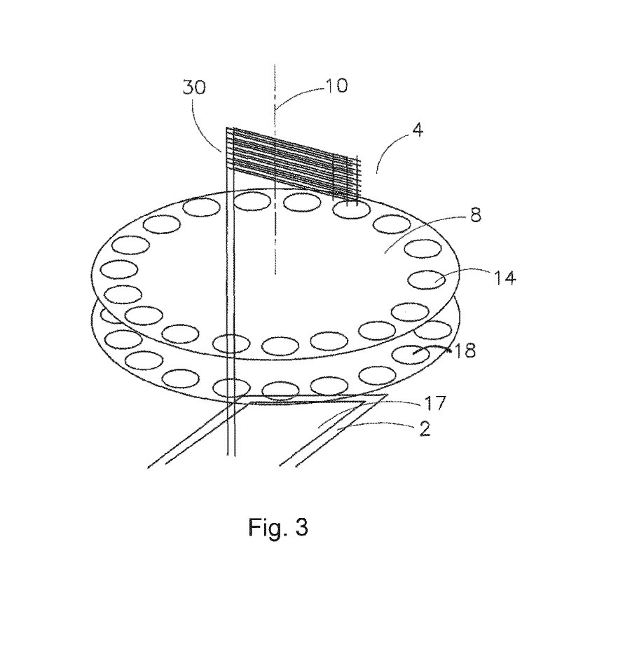

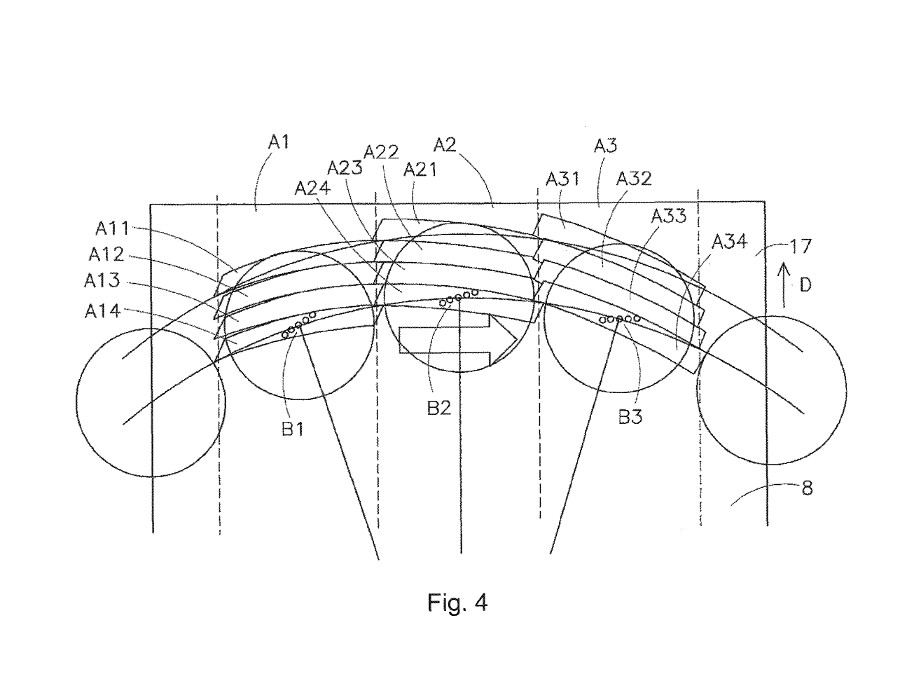

FIG. 3 depicts a highly schematic, perspective view of the rotating frame 8 provided with lenses 14, 18 at its perimeter. A plurality of beams, in this example 10 beams, are incident onto one of the lenses and projected onto a target portion of the substrate 17 held by the substrate table 2. In an embodiment, the plurality of beams are arranged in a straight line. The rotatable frame is rotatable about axis 10 by means of an actuator (not shown). As a result of the rotation of the rotatable frame 8, the beams will be incident on successive lenses 14, 18 (field lens 14 and imaging lens 18) and will, incident on each successive lens, be deflected thereby so as to travel along a part of the surface of the substrate 17, as will be explained in more detail with reference to FIG. 4. In an embodiment, each beam is generated by a respective source, i.e. a self-emissive contrast device, e.g. a laser diode (not shown in FIG. 3). In the arrangement depicted in FIG. 3, the beams are deflected and brought together by a segmented mirror 30 in order to reduce a distance between the beams, to thereby enable a larger number of beams to be projected through the same lens and to achieve resolution requirements to be discussed below.

As the rotatable frame rotates, the beams are incident on successive lenses and, each time a lens is irradiated by the beams, the places where the beam is incident on a surface of the lens, moves. Since the beams are projected on the substrate differently (with e.g. a different deflection) depending on the place of incidence of the beams on the lens, the beams (when reaching the substrate) will make a scanning movement with each passage of a following lens. This principle is further explained with reference to FIG. 4. FIG. 4 depicts a highly schematic top view of a part of the rotatable frame 8. A first set of beams is denoted by B1, a second set of beams is denoted by B2 and a third set of beams is denoted by B3. Each set of beams is projected through a respective lens set 14, 18 of the rotatable frame 8. As the rotatable frame 8 rotates, the beams B1 are projected onto the substrate 17 in a scanning movement, thereby scanning area A14. Similarly, beams B2 scan area A24 and beams B3 scan area A34. At the same time of the rotation of the rotatable frame 8 by a corresponding actuator, the substrate 17 and substrate table are moved in the direction D, which may be along the X axis as depicted in FIG. 2), thereby being substantially perpendicular to the scanning direction of the beams in the area's A14, A24, A34. As a result of the movement in direction D by a second actuator (e.g. a movement of the substrate table by a corresponding substrate table motor), successive scans of the beams when being projected by successive lenses of the rotatable frame 8, are projected so as to substantially abut each other, resulting in substantially abutting areas A11, A12, A13, A14 (areas A11, A12, A13 being previously scanned and A14 being currently scanned as shown in FIG. 4) for each successive scan of beams B1, areas A21, A22, A23 and A24 (areas A21, A22, A23 being previously scanned and A24 being currently scanned as shown in FIG. 4) for beams B2 and areas A31, A32, A33 and A34 (areas A31, A32, A33 being previously scanned and A34 being currently scanned as shown in FIG. 4) for beams B3. Thereby, the areas A1, A2 and A3 of the substrate surface may be covered with a movement of the substrate in the direction D while rotating the rotatable frame 8. The projecting of multiple beams through a same lens allows processing of a whole substrate in a shorter timeframe (at a same rotating speed of the rotatable frame 8), since for each passing of a lens, a plurality of beams scan the substrate with each lens, thereby allowing increased displacement in the direction D for successive scans. Viewed differently, for a given processing time, the rotating speed of the rotatable frame may be reduced when multiple beams are projected onto the substrate via a same lens, thereby possibly reducing effects such as deformation of the rotatable frame, wear, vibrations, turbulence, etc. due to high rotating speed. In an embodiment, the plurality of beams are arranged at an angle to the tangent of the rotation of the lenses 14, 18 as shown in FIG. 4. In an embodiment, the plurality of beams are arranged such that each beam overlaps or abuts a scanning path of an adjacent beam.

A further effect of the aspect that multiple beams are projected at a time by the same lens, may be found in relaxation of tolerances. Due to tolerances of the lenses (positioning, optical projection, etc), positions of successive areas A11, A12, A13, A14 (and/or of areas A21, A22, A23 and A24 and/or of areas A31, A32, A33 and A34) may show some degree of positioning inaccuracy in respect of each other. Therefore, some degree of overlap between successive areas A11, A12, A13, A14 may be required. In case of for example 10% of one beam as overlap, a processing speed would thereby be reduced by a same factor of 10% in case of a single beam at a time through a same lens. In a situation where there are 5 or more beams projected through a same lens at a time, the same overlap of 10% (similarly referring to one beam example above) would be provided for every 5 or more projected lines, hence reducing a total overlap by a factor of approximately 5 or more to 2% or less, thereby having a significantly lower effect on overall processing speed. Similarly, projecting at least 10 beams may reduce a total overlap by approximately a factor of 10. Thus, effects of tolerances on processing time of a substrate may be reduced by the feature that multiple beams are projected at a time by the same lens. In addition or alternatively, more overlap (hence a larger tolerance band) may be allowed, as the effects thereof on processing are low given that multiple beams are projected at a time by the same lens.

Alternatively or in addition to projecting multiple beams via a same lens at a time, interlacing techniques could be used, which however may require a comparably more stringent matching between the lenses. Thus, the at least two beams projected onto the substrate at a time via the same one of the lenses have a mutual spacing, and the apparatus may be arranged to operate the second actuator so as to move the substrate with respect to the optical column to have a following projection of the beam to be projected in the spacing.

In order to reduce a distance between successive beams in a group in the direction D (thereby e.g. achieving a higher resolution in the direction D), the beams may be arranged diagonally in respect of each other, in respect of the direction D. The spacing may be further reduced by providing a segmented mirror 30 in the optical path, each segment to reflect a respective one of the beams, the segments being arranged so as to reduce a spacing between the beams as reflected by the mirrors in respect of a spacing between the beams as incident on the mirrors. Such effect may also be achieved by a plurality of optical fibers, each of the beams being incident on a respective one of the fibers, the fibers being arranged so as to reduce along an optical path a spacing between the beams downstream of the optical fibers in respect of a spacing between the beams upstream of the optical fibers.

Further, such effect may be achieved using an integrated optical waveguide circuit having a plurality of inputs, each for receiving a respective one of the beams. The integrated optical waveguide circuit is arranged so as to reduce along an optical path a spacing between the beams downstream of the integrated optical waveguide circuit in respect of a spacing between the beams upstream of the integrated optical waveguide circuit.

A system may be provided to control the focus of an image projected onto a substrate. The arrangement may be provided to adjust the focus of the image projected by part or all of an optical column in an arrangement as discussed above.

In an embodiment the projection system projects the at least one radiation beam onto a substrate formed from a layer of material above the substrate 17 on which a device is to be formed so as to cause local deposition of droplets of the material (e.g. metal) by a laser induced material transfer.

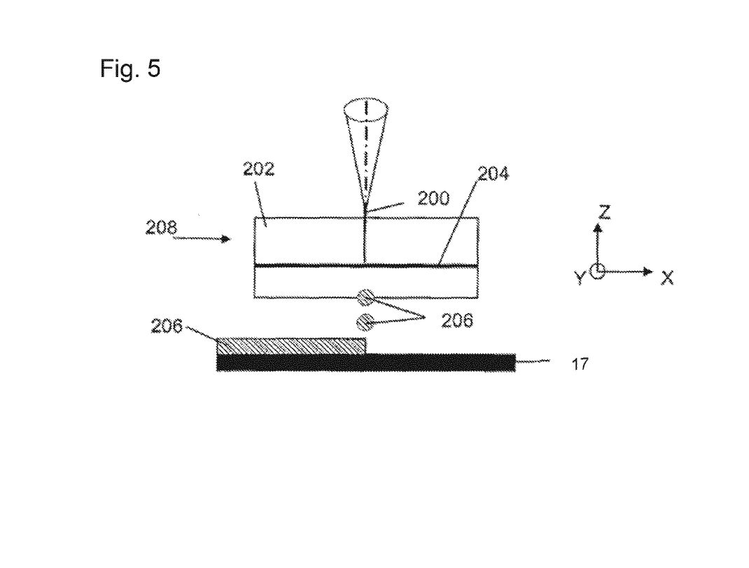

Referring to FIG. 5, the physical mechanism of laser induced material transfer is depicted. In an embodiment, a radiation beam 200 is focused through a substantially transparent material 202 (e.g., glass) at an intensity below the plasma breakdown of the material 202. Surface heat absorption occurs on a substrate formed from a donor is material layer 204 (e.g., a metal film) overlying the material 202. The heat absorption causes melting of the donor material 204. Further, the heating causes an induced pressure gradient in a forward direction leading to forward acceleration of a donor material droplet 206 from the donor material layer 204 and thus from the donor structure (e.g., plate) 208. Thus, the donor material droplet 206 is released from the donor material layer 204 and is moved (with or without the aid of gravity) toward and onto the substrate 17 on which a device is to be formed. By pointing the beam 200 on the appropriate position on the donor plate 208, a donor material pattern can be deposited on the substrate 17. In an embodiment, the beam is focused on the donor material layer 204.

In an embodiment, one or more short pulses are used to cause the transfer of the donor material. In an embodiment, the pulses may be a few picoseconds or femtoseconds long to obtain quasi one dimensional forward heat and mass transfer of molten material. Such short pulses facilitate little to no lateral heat flow in the material layer 204 and thus little or no thermal load on the donor structure 208. The short pulses enable rapid melting and forward acceleration of the material (e.g., vaporized material, such as metal, would lose its forward directionality leading to a splattering deposition). The short pulses enable heating of the material to just above the heating temperature but below the vaporization temperature. For example, for aluminum, a temperature of about 900 to 1000 degrees Celsius is desirable.

In an embodiment, through the use of a laser pulse, an amount of material (e.g., metal) is transferred from the donor structure 208 to the substrate 17 in the form of 100-1000 nm droplets. In an embodiment, the donor material comprises or consists essentially of a metal. In an embodiment, the metal is aluminum. In an embodiment, the material layer 204 is in the form a film. In an embodiment, the film is attached to another body or layer. As discussed above, the body or layer may be a glass.

In an embodiment, the programmable patterning device comprises self-emissive contrast elements that benefit from being driven constantly. In an embodiment, the self-emissive contrast elements comprise laser diodes. Laser diodes only start “lasering” above a certain threshold current. The threshold current may be about 1 to 2% of maximum current, for example. Below the threshold current the laser diode acts like an LED or is off. In an embodiment the laser diodes are maintained above the threshold current in order to avoid timing errors associated with the stochastic starting of the laser mode. Such timing errors can be of the order of 200 ps or greater, which could lead to spot position errors of 20 nm or greater.

Maintaining laser diodes above the threshold current avoids timing errors but means that the laser diodes all contribute to a background exposure. Where the laser diodes contribute in a non-uniform manner to the dose distribution formed on the substrate, the background exposure will also be non-uniform. A non-uniform background level can be difficult to correct for and can have a detrimental effect on image quality.

Additionally, it is expected that rapid switching of the output power of a laser diode will have a negative effect on the lifetime of that laser diode. Reducing the lifetimes of the laser diodes increases the frequency with which the laser diodes need to be replaced, increasing expense and inconvenience.

In an embodiment, it is proposed to address one or more issues mentioned herein or in the art by adapting the device configuration at or near the radiation sources directly.

In the description below, reference is made to optical fibers and to waveguides. An optical fiber is considered to be a type of waveguide and therefore falls within the scope of the term “waveguide”.

In an embodiment, it is proposed to use one or more higher wavelength sources, such as one or more 810 nm laser diodes (rather than one or more 405 nm laser diodes). In order to achieve the desired resolution at target level, the 810 nm radiation is transported at that wavelength with one or more optical fibers and subsequently converted to 405 nm radiation using a non linear optical crystal (which may be referred to as a “conversion crystal”). An example of a conversion crystal is PPKTP (periodically poled potassium titanyl phosphate).

In an embodiment, a multi-pass configuration is used to increase efficiency. In a multi-pass configuration, radiation to be converted to a higher frequency passes through the conversion crystal multiple times.

In an embodiment, one of the following configurations is adopted: 1) the conversion crystal is placed after the fiber that emits 810 nm radiation; or 2) the conversion crystal is integrated into an optical waveguide. In an embodiment, the fiber that emits the 810 nm radiation brings the radiation to the optical waveguide. Inside the waveguide the conversion is done and at the exit is, for example, 405 nm wavelength radiation.

In an embodiment, a filter for the high wavelength radiation that is not converted is provided.

In an embodiment, conversion to a wavelength smaller than 405 nm is implemented. In an embodiment, 405 nm radiation is frequency converted to 202 nm. In another embodiment radiation having a wavelength that is higher than 810 nm is used in combination with 3rd harmonic generation to bring the wavelength down below 405 nm.

In an embodiment, the conversion crystal is provided at the exit of the optical fiber. This location provides a benefit particularly where a set of microlenses is provided. In an embodiment, the microlenses give small angles and a relatively large footprint (˜diameter 100 μm). This facilitates use of a long crystal (˜20 mm). A long crystal facilitates high single pass efficiency (expected up to about 1%). Multi-pass can be used to improve efficiency further.

In an embodiment, one or more VECSELs (or Vcsel) are used as a radiation source instead of or in addition to a laser diode. A vertical-external-cavity surface-emitting-laser (VECSEL) is a small semiconductor laser that emits radiation perpendicular to the surface of the substrate out of which the emitter is made. Compare this to a laser diode that emits radiation in the plane of the substrate. A consequence of the geometry is that a laser diode is cut out of the wafer and individually mounted in a package. A VECSEL, in contrast, can be made in an individually addressable array at small pitch (e.g. 400 microns). In this way the demagnification of the optics can be reduced from e.g. 500× to 20× making tolerance issues small. Since the emission area is larger (e.g. 10-15 microns diameter) beam pointing is also more stable than with a laser diode.

A VECSEL is not as commonly used as a laser diode. Currently such a laser is available mainly as made of GaAs, and emits radiation from 780-1150 nm. In an embodiment, such a VECSEL is configured to emit at about 810 nm and the output is frequency doubled to 405 nm.

When the VECSEL is made of GaN primary emission at 405 nm is possible since this is the same material used for a laser diode.

Typically, a laser diode can emit up to 250 mW from a single emitter. A frequency doubled VECSEL of GaAs can emit about 20 mW per emitter while a GaN emitter can deliver up to 1 mW. In an embodiment, each laser diode is replaced by multiple VECSEL emitters to deliver the desired amount of radiation per radiation beam. This approach can introduce a wanted side-effect: redundancy in the system, since each spot on the target can be addressed by multiple emitters. This means that when there is one emitter broken only part of the energy is missing.

Increasing the frequency of radiation beams after generation of the radiation makes it possible to use a cheaper laser source in the context of lithography. For example, a laser diode at 810 nm or a VECSEL can be used.

Lifetime issues with a high wavelength is much less, meaning fiber may be used for the lifetime of the system, and not as a replaceable item.

The use of frequency doubling/tripling provides the basis for working with a wavelength even below 405 nm, which allows for future customer resolution requirements.

The non-linear nature of the frequency conversion will also effectively reduce the background radiation when a laser-diode emitter is maintained above a threshold firing state. The frequency conversion efficiency is less for lower input powers than for higher input powers. Thus, the relative level of background radiation at the desired output wavelength will be lowered by the conversion process.

A VECSEL has an additional benefit of array fabrication at a small pitch which reduces the complexity of illumination optics.

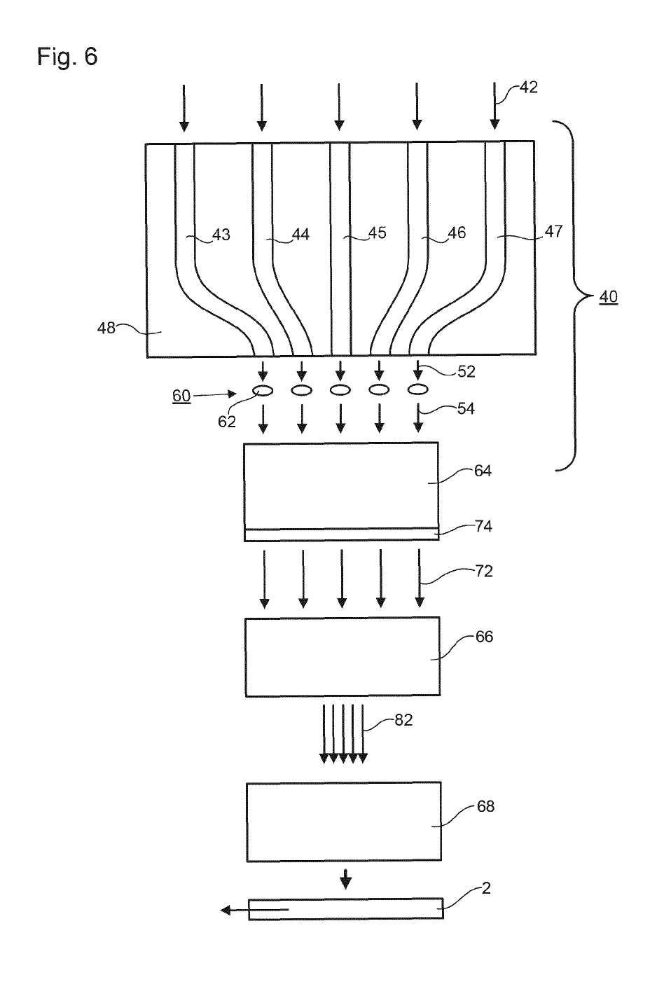

FIG. 6 depicts an example configuration. An assembly 40 is provided to modify one or more properties of a plurality of input radiation beams 42. The plurality of input beams 42 may be output from, for example, a corresponding plurality of self-emissive contrast elements, for example laser diodes or VECSELs. In the embodiment shown, the assembly 40 comprises a plurality of waveguides 43-47 that are configured to guide the plurality of radiation beams closer together. The average separation of the radiation beams 52 output from the plurality of waveguides 43-47 is smaller than the average separation of the input radiation beams 42.

In the embodiment shown, an array 60 of microlenses 62 is provided at the output from the plurality of waveguides 43-47. In an embodiment, each of the plurality of microlenses 62 is configured to reduce the divergence of radiation output from each of the plurality of waveguides 43-47. Thus, in an embodiment, the beams 54 output from the microlenses 62 are more collimated than the input beams 52.

The assembly 40 further comprises a frequency multiplying device 64. The frequency multiplying device 64 is configured to receive the plurality of radiation beams 54 guided by the plurality of waveguides 43-47 (and in this embodiment subsequently re-directed by the microlenses 62) and configured to generate a corresponding plurality of radiation beams 72 having frequencies that are an integer multiple higher. In an embodiment, the integer multiple is two, which may be referred to as frequency doubling. In another embodiment, the integer multiple is three, which may be referred to as frequency tripling.

In an embodiment, the plurality of radiation beams 72 output from the frequency multiplying device 64 comprises beams having a wavelength that is suitable for a lithography process (e.g. sufficiently low to cause the desired reaction in a resist formed on a substrate onto which the radiation beam is projected). In an embodiment, the wavelength is equal to or less than 450 nm.

In an embodiment, the frequency multiplying device 64 uses second or third harmonic generation to generate the radiation beams 72 of higher frequency. As discussed above, second or third harmonic generation can be performed using a conversion crystal having a non-linear optical property. The conversion efficiency, however, is typically relatively low. For each pass of the radiation to be converted through the crystal, only a small percentage is converted to higher frequency (e.g. 1% or less). The efficiency can be increased by arranging the radiation to pass through the crystal multiple times (also referred to as multipass). However, it is still possible that a significant amount of unconverted radiation will remain. In the embodiment shown in FIG. 6, such unconverted radiation is removed by a filter 74.

In the embodiment shown, the frequency multiplying device 64 comprises a conversion material having a non-linear optical property that is physically separate from the structure 48 having the plurality of waveguides 43-47. In an embodiment, the frequency multiplying device comprises a conversion material that is integrated into one or more of the plurality of waveguides 43-47 and/or integrated into one or more additional waveguides connected to the plurality of waveguides 43-47.

In an embodiment, the input radiation 42 has a wavelength of about 810 nm and the output radiation 72 has a wavelength of about 405 nm.

In the embodiment shown in FIG. 6, the plurality of radiation beams 72 output from the frequency multiplying device 64 are brought closer optically (demagnified) by a stationary lens system 66. The output 82 from the stationary lens system 66 is then provided to a moving lens system 68 which is configured to project the beams at the desired pitch onto a target moving underneath the lens system 68 on, for example, a substrate table 2. When applied to embodiments of the type depicted in FIGS. 1-4, the stationary lens system 68 would comprise the lens 12 and the moving lens system would comprise the lenses 14 and 18.

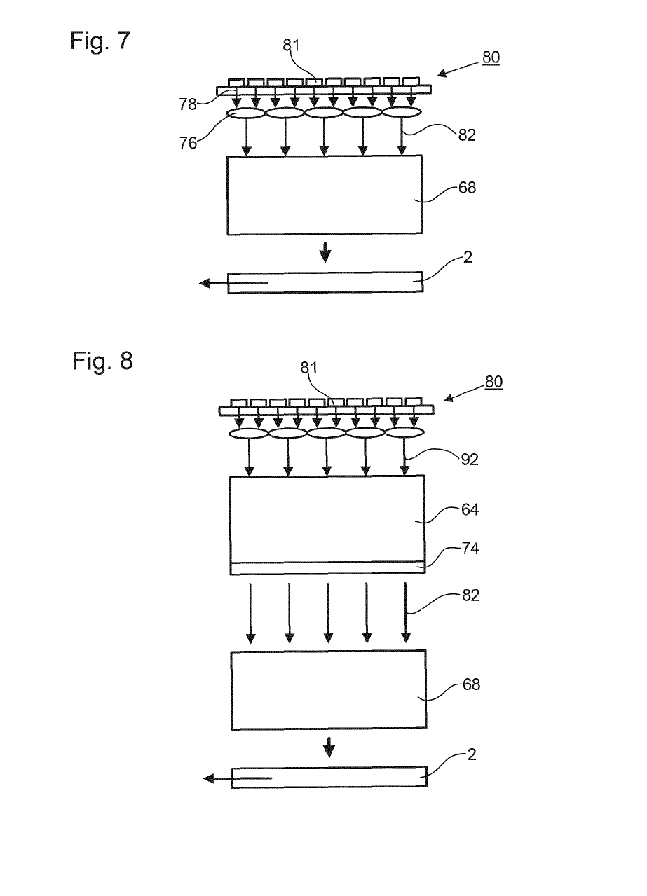

FIG. 7 depicts an embodiment in which a plurality 80 of vertical-external-cavity surface-emitting-lasers (VECSELs) 81 are used as the radiation source. As mentioned above, VECSELs can be configured to emit radiation directly at much smaller pitch than a corresponding plurality of laser diodes. As a result, the subsequent optical demagnification may be reduced. In order to increase power output per radiation beam, groups of VECSELs may be used together to contribute to the radiation in one output radiation beam 82. An optical system 76 is provided to convert multiple VECSEL emissions 78 from each group to a single output radiation beam 82.

In an embodiment, the pitch or average separation between the radiation beams 82 output from the plurality of VECSELs, even when a group of VECSELs are used to generate each radiation beam 82, is already at a magnification that is comparable to the radiation beams 82 output from the fixed lens system 66 of an embodiment of the type illustrated in FIG. 6. Thus, no equivalent of the fixed lens system 66 may be required, saving costs. In an embodiment, a further fixed lens may be provided, but the specifications on any such further fixed lens system, in terms of demagnification for example, should be much lower than for the fixed lens system 66.

In an embodiment, the output radiation beams 82 from the plurality of VECSELS 80 have a wavelength that is 450 nm or less. Thus, in such an embodiment a frequency multiplying device (e.g., device 64) may not be needed in order to generate radiation suitable for lithography. In an embodiment such functionality is achieved using a GaN-based VECSEL. In an embodiment, such functionality is achieved by integrating a frequency multiplying device into each VECSEL unit or group of VECSELs units that is configured to increase the frequency of radiation output by an integer multiple (e.g. by second or third harmonic generation). In an embodiment, the VECSELs are configured to output radiation having a wavelength of about 405 nm.

FIG. 8 illustrates an embodiment in which the VECSELs 81 are configured in a system to output radiation having a wavelength about 405 nm. In an example of such an embodiment, the VECSELs 81 are configured to emit radiation 92 having a wavelength of about 810 nm. In the embodiment shown, a frequency multiplying device 64 and filter 74 are used to provide a plurality of radiation beams 82 having a wavelength suitable for lithography. In an example embodiment of this type, the VECSELs are configured to emit radiation in the range of 780nm-1150 nm, for example at 810 nm. In an embodiment, the VECSELs are GaAs-based VECSELs.

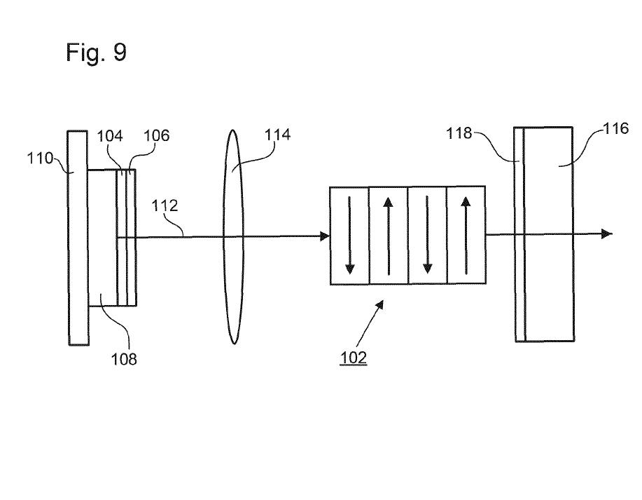

FIG. 9 depicts an example VECSEL unit (produced by Princeton Optronics) comprising an integrated frequency multiplying device 102. In this example the frequency multiplying device comprises a conversion crystal of PPLN (periodically poled lithium niobate). The VECSEL comprises a low doping GaAs substrate 104 with an anti-reflective dielectric coating 106. Region 108 comprises stacks of multiple quantum wells grown on a partially reflective n-type distributed Bragg reflector (DBR). A highly reflective p-type DBR mirror is added to the structure to form an internal optical cavity. A heat-spreader 110, optionally connected to a heat-sink, is provided to remove heat. Radiation 112 is output from the substrate side of the device (bottom emitting). A lens 114 focuses the emitted radiation onto the PPLN crystal. In this example, an external cavity is formed by glass mirror 116 and partially reflective dielectric coating 118 to provide the feedback for lasing. A 10 mm long periodically poled PPLN crystal is used as the second harmonic generating crystal. The periodic poling maintains phase matching between the fundamental 980 nm and the second harmonic 490 nm wavelength and provides a long conversion region. To enhance intra-cavity power the dielectric coating 118 is highly reflective at the fundamental wavelength and partially transmissive at the second harmonic wavelength.

In an embodiment, the plurality 80 of VECSELs are provided in an individually addressable array. In an embodiment, the average separation between individual VECSELs is less than or equal to 1000 microns. In an embodiment, the average separation is between 300 and 500 microns.

In accordance with a device manufacturing method, a device, such as a display, integrated circuit or any other item may be manufactured from the substrate on which the pattern has been projected.

In an embodiment, there is provided an assembly to modify a property of a plurality of radiation beams, the assembly comprising: a plurality of waveguides configured to guide the plurality of radiation beams closer together; and a frequency multiplying device configured to receive the plurality of radiation beams guided by the plurality of waveguides and generate a corresponding plurality of radiation beams having frequencies that are an integer multiple higher.

In an embodiment, the frequency multiplying device is configured to use second harmonic generation to double the radiation frequency. In an embodiment, the frequency multiplying device is configured to use third harmonic generation to triple the radiation frequency. In an embodiment, the plurality of radiation beams output from the frequency multiplying device comprises beams having a wavelength of 450 nm or lower. In an embodiment, the assembly further comprises a filter configured to remove radiation output by the frequency multiplying device that has the same frequency as radiation input to the frequency multiplying device. In an embodiment, the frequency multiplying device is configured to allow each of one or more of the radiation beams to pass through a conversion material having a non-linear optical property a plurality of times in order to increase the proportion of the radiation beam that is converted to higher frequency radiation. In an embodiment, the frequency multiplying device comprises a conversion material having a non-linear optical property that is integrated into one or more of the plurality of waveguides and/or integrated into one or more additional waveguides connected to the plurality of waveguides. In an embodiment, the input to the frequency multiplying device comprises a plurality of radiation beams having a wavelength of about 810 nm. In an embodiment, the input to the frequency multiplying device comprises a plurality of radiation beams having a wavelength of about 405 nm. In an embodiment, the assembly further comprises a plurality of microlenses provided at the output from the plurality of waveguides, each of the plurality of microlenses configured to reduce divergence of radiation output from the plurality of waveguides. In an embodiment, the frequency multiplying device is positioned immediately after the plurality of microlenses. In an embodiment, one or more of the plurality of waveguides comprises an optical fiber.

In an embodiment, there is provided an exposure apparatus, comprising: a radiation source to provide a plurality of individually controllable radiation beams, the radiation source comprising: a plurality of waveguides configured to guide the plurality of radiation beams closer together, and a frequency multiplying device configured to receive the plurality of radiation beams guided by the plurality of waveguides and generate a corresponding plurality of radiation beams having frequencies that are an integer multiple higher; and a projection system for projecting each of the radiation beams onto a respective location on a target.

In an embodiment, the apparatus comprises an assembly as described herein configured to increase the frequency of the radiation beams output by the radiation source by an integer multiple. In an embodiment, the radiation source comprises a plurality of self-emissive contrast elements. In an embodiment, the plurality of self-emissive contrast elements comprises a plurality of laser diodes. In an embodiment, the plurality of self-emissive contrast elements comprises a plurality of vertical-external-cavity surface-emitting-lasers (VECSELs).

In an embodiment, there is provided an exposure apparatus, comprising: a radiation source to provide a plurality of individually controllable radiation beams, the radiation source comprising a plurality of vertical-external-cavity surface-emitting-lasers (VECSELs); and a projection system configured to project each of the radiation beams onto a respective location on a target.

In an embodiment, the VECSELs are configured to emit radiation at a wavelength in the range of 780-1150 nm. In an embodiment, the VECSELs are GaAs-based VECSELs. In an embodiment, the VECSELs are configured to emit radiation at a wavelength of about 405 nm. In an embodiment, the VECSELs are GaN-based VECSELs. In an embodiment, the VECSELs comprise an integrated frequency multiplying device configured to increase the frequency of radiation emitted by the VECSELs by an integer multiple. In an embodiment, the radiation source is configured to use a group comprising a plurality of the VECSELs to generate each of the radiation beams. In an embodiment, the VECSELs are provided in an individually addressable array. In an embodiment, the average spacing of VECSELs is less than or equal to 1000 microns. In an embodiment, the average spacing of VECSELs is between 300 and 500 micron. In an embodiment, the projection system comprises a stationary part and a moving part. In an embodiment, the moving part is configured to rotate relative to the stationary part.

In an embodiment, there is provided a method of modifying a property of a plurality of radiation beams, the method comprising: using a plurality of waveguides to guide the radiation beams closer together; and using a frequency multiplying device to receive the plurality of radiation beams guided by the plurality of waveguides and generate a corresponding plurality of radiation beams having frequencies that are an integer multiple higher.

In an embodiment, there is provided a device manufacturing method, comprising: using a plurality of waveguides to guide a plurality of individually controllable radiation beams closer together; using a frequency multiplying device to receive the plurality of radiation beams guided by the plurality of waveguides and generate a corresponding plurality of radiation beams having frequencies that are an integer multiple higher; and projecting each of the radiation beams onto a respective location on a target.

In an embodiment, there is provided a device manufacturing method, comprising: providing a plurality of individually controllable radiation beams using a plurality of vertical-external-cavity surface-emitting-lasers (VECSELs); and projecting each of the radiation beams onto a respective location on a target.

Although specific reference may be made in this text to the use of a lithographic or exposure apparatus in the manufacture of ICs, it should be understood that the apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The term “lens”, where the context allows, may refer to any one of various types of optical components, including refractive, diffractive, reflective, magnetic, electromagnetic and electrostatic optical components or combinations thereof.

The descriptions above are intended to be illustrative, not limiting. Thus, it will be apparent to one skilled in the art that modifications may be made to the invention as described without departing from the scope of the claims set out below.

1. An assembly to modify a property of a plurality of radiation beams, the assembly comprising:
a plurality of waveguides configured to guide the plurality of radiation beams closer together; and
a frequency multiplying device configured to receive the plurality of radiation beams guided by the plurality of waveguides and generate a corresponding plurality of radiation beams having frequencies that are an integer multiple higher.

2. The assembly according to claim 1, wherein the frequency multiplying device is configured to use second harmonic generation to double the radiation frequency.

3. The assembly according to claim 1, wherein the frequency multiplying device is configured to use third harmonic generation to triple the radiation frequency.

4. The assembly according to claim 1, further comprising a filter configured to remove radiation output by the frequency multiplying device that has the same frequency as radiation input to the frequency multiplying device.

5. The assembly according to claim 1, wherein the frequency multiplying device is configured to allow each of one or more of the radiation beams to pass through a conversion material having a non-linear optical property a plurality of times in order to increase the proportion of the radiation beam that is converted to higher frequency radiation.

6. The assembly according to claim 1, wherein the frequency multiplying device comprises a conversion material having a non-linear optical property that is integrated into one or more of the plurality of waveguides and/or integrated into one or more additional waveguides connected to the plurality of waveguides.

7. The assembly according to claim 1, further comprising a plurality of microlenses provided at the output from the plurality of waveguides, each of the plurality of microlenses configured to reduce divergence of radiation output from the plurality of waveguides.

8. The assembly according to claim 7, wherein the frequency multiplying device is positioned immediately after the plurality of microlenses.

9. The assembly according to claim 1, wherein one or more of the plurality of waveguides comprises an optical fiber.

10. An exposure apparatus, comprising:
a radiation source to provide a plurality of individually controllable radiation beams, the radiation source comprising:
a plurality of waveguides configured to guide the plurality of radiation beams closer together, and
a frequency multiplying device configured to receive the plurality of radiation beams guided by the plurality of waveguides and generate a corresponding plurality of radiation beams having frequencies that are an integer multiple higher; and
a projection system for projecting each of the radiation beams onto a respective location on a target.

11. The apparatus according to claim 10, further comprising:
an assembly configured to modify a property of a plurality of radiation beams, the assembly comprising a plurality of waveguides configured to guide the plurality of radiation beams closer together and a frequency multiplying device confiured to receive the plurality of radiation beams guided by the plurality of waveguides and generate a corresponding plurality of radiation beams having frequencies that are an integer multiple higher.

12. The apparatus according to claim 10, wherein the radiation source comprises a plurality of self-emissive contrast elements such as vertical-external-cavity surface-emitting-lasers (VECSELs).

13. An exposure apparatus, comprising:
a radiation source to provide a plurality of individually controllable radiation beams, the radiation source comprising a plurality of vertical-external-cavity surface-emitting-lasers (VECSELs); and
a projection system configured to project each of the radiation beams onto a respective location on a target.

14. The apparatus according to claim 12, wherein the radiation source is configured to use a group comprising a plurality of the VECSELs to generate each of the radiation beams.

15. The apparatus according to claim 12, wherein the VECSELs are provided in an individually addressable array.
